(19) United States
(12) Patent Application Publication
(10) Pub. No.: US 2006/0140174 A1
(43) Pub. Date: Jun. 29, 2006

(54) VoIP (voice over internet protocol) call processing

(76) Inventor: Eung-Moon Yeom, Suwon-si (KR)

Correspondence Address: Robert E. Bushnell;Suite 300, 1522 K Street, N.W., Washington, DC, 20005, US

(21) Appl. No.: 11/297,480

(22) Filed: Dec. 9, 2005

(30) Foreign Application Priority Data
Dec. 29, 2004 (KR) 2004-114986

(51) Int. Cl. H04L 12/56; H04L 12/66; G01R 31/08; H04L 1/00; H04L 12/26; H04L 12/28

(52) U.S. Cl. 370/352; 370/229; 370/395.21

(57) ABSTRACT

In a Voice over Internet Protocol (VoIP) call processing system and method, a first unit is adapted to setup address information, for a terminal requesting a call connection during VoIP call signaling, as Quality of Service (QoS) guarantee information for a VoIP service, and to delete the QoS guarantee information upon releasing the VoIP call; and a second unit is adapted to guarantee a QoS for the VoIP service according to the QoS guarantee information during the VoIP call.

### CLAIM OF PRIORITY

This application makes reference to, incorporates the same herein, and claims all benefits accruing under 35 U.S.C. § 119 from an application for SYSTEM AND METHOD FOR PROCESSING VoIP CALL earlier filed in the Korean Intellectual Property Office on 29 December 2004 and there duly assigned Ser. No. 2004-0114986.

### BACKGROUND OF THE INVENTION

1. Field of the Invention

The present invention relates to Voice over Internet Protocol (VoIP) call processing, and more specifically, to a VoIP call processing system and method in which a VoIP IP address and port number for VoIP service, obtained by implementing a VoIP Application Level Gateway (ALG) function when processing a VoIP signal, are used to guarantee Quality of Service (QoS) with respect to the VoIP service, in order to overcome a limitation of the VoIP service occurring when a private network operating a private IP is coupled with a public network using a public IP through Network Address Translation/Port Translation (NAT/PT).

2. Description of the Related Art

With widespread use of the Internet, interest in VoIP service has been increasing. The Internet service enables users to use long-distance and international telephone services in an Internet or Intranet environment at the cost of local telephone service, by embodying telephone services integrally using an Internet Protocol (IP) network.

A signaling protocol to embody VoIP includes Session Initiation Protocol (SIP), Media Gateway Control Protocol (MGCP), H.323 and so on.

The SIP is an application layer control protocol based on simple text that enables one or more participants to generate/correct/terminate sessions all together. Sessions include a video conference, a telephone call, an interview, an event notification, instant messaging, and so on, using the Internet.

The MGCP is a standard protocol for a signaling and session management needed during a multimedia conference, and is also known as ‘H.248’ or ‘Megaco’.

H.323 is a standard defined by ‘ITU-T’ that is used to transmit multimedia video conference data through a network using a packet exchange method such as TCP/IP.

In the IPv4 address system, gradual exhaustion of public IP addresses which eventually leads to a shortage of public IP addresses can be overcome using Network Address Translation (NAT) technology.

NAT, which enables a small number of public IP addresses to be used, is described in a general agreement of ‘Request for Comments (RFC) 1631’ as a solution to the exhaustion of public IP addresses in IP networks.

Network Address Translation/Port Translation (NAT/PT) technology, one type of NAT technology, is widely used to overcome public IP address deficiency or to conceal an internal network configuration, and is generally installed in a router or a firewall to convert an internal private IP into a public IP that can be routed on the Internet and to convert TCP/UDP port numbers as well.

When a host of a private network made by using a private IP wishes to communicate with a host of a global network, the host of the private network communicates using a private IP address assigned to itself as a source address. Since the private IP address belongs to a meaningless address system in the global network, it should be converted into a meaningful public IP address. A global IP address assigned in the NAT/PT is used to convert addresses, and such global IP addresses are managed in a pool of one or more IP addresses.

The source address of a packet must be converted into a global IP address when data is transmitted out of the private network, and a destination address of a packet must be converted into the private IP address when data is transmitted from the global network into the private network.

Typically, NAT/PT is implemented in a router that connects a private network operating with a private IP to a global network operating by routing according to a public IP.

The router to perform NAT/PT enables several hosts in the private network to share a global IP and to communicate with a global network at the same time by converging IP addresses, which are information of a Layer 3, and supporting N: 1 binding through port conversion of the TCP/UDP Layer (network Layer).

Although NAT/PT is a network address conversion method to maximize an IP address utilizing ratio using port information of a transport Layer as well as destination address information of a network Layer, its process is complicated and has a low speed since the IP Layer and the TCP/UDP Layer must be considered to convert an IP address. Furthermore, there is a limitation in that services sensitive to port numbers (Talk, Real Player, etc.) cannot be performed unless a corresponding ALG is used.

NAT/PT has problems such as it being necessary to reassemble packets which have been divided up and transferred in order to make a complete packet.

Since Internet applications such as H.323, FTP, and Messenger include identification information of a packet generation host (source address, source port) in a Protocol Data Unit (PDU) of the packet, they cannot be applied in network address conversion equipment without an ALG. Accordingly, a lot of ALGs are required to support various Internet applications.

Thus, as NAT/PT is performed in the router, the router typically includes an ALG function capable of analyzing the PDU of a packet.

Accordingly, when VoIP signaling is generated in a host of a private network and transmitted to a public network, the router captures and analyzes the VoIP signaling and converts private IP information included in the IP header of the VoIP signaling into public IP information through the NAT/PT. The router also converts source address information included n the PDU of the VoIP signaling into the IP address and public port by performing the ALG function, and then transmits them to the public network.

A QoS guarantee for the VoIP service is an important problem in a network having the above-described configuration.

Methods of guaranteeing QoS for such a VoIP service include congestion control, queue management, Type of Service (ToS) processing, and so on.

In the congestion control method, a congestion phenomenon caused by network traffic is avoided by establishing an order for processing IP addresses and port numbers in advance.

In the queue management method, packets are gathered in a queue awaiting transmission to a buffer of a transmission link and selected for transmission according to a scheduling method. It is necessary for packets needed to guarantee QoS to be put into the highest priority queue. For this purpose, the IP address and port number used in the service needing the QoS guarantee must be previously set up.

In the ToS processing method, a Class of Service (CoS) for each packet is determined using a priority of three bits in the ToS field included in the packet transmitted to the network. That is, in order to determine the priority of the three bits in the ToS field, a user has to know the IP address and port number set up previously.

As described above, in congestion control, queue management, and ToS processing, to guarantee the QoS, the IP address and port number used in the service needing the QoS must be statically set up in advance by an equipment manager.

Likewise, in congestion control, queue management, and ToS processing, to guarantee the QoS of the VoIP service, a region for the IP address and port number for the VoIP service must be statically set up. This is inconvenient because the user must know the port allocation policies of all manufacturers of VoIP terminals to use the VoIP service with VoIP terminals made by various manufacturers.

When the statically set up IP address is simultaneously used in the VoIP service and IP application services (FTP, Telnet and so on), the QoS for the VoIP service cannot be guaranteed.

In other words, since the VoIP service and IP application service needing the QoS guarantee are performed through a single, statically set up IP address, congestion control, queue management, and ToS processing for the VoIP service cannot be performed. Accordingly, the QoS for the VoIP service cannot be guaranteed.

### SUMMARY OF THE INVENTION

It is, therefore, an object of the present invention to provide a Voice over Internet Protocol (VoIP) call processing system and method, where a VoIP IP address and port number for VoIP service, obtained by implementing a VoIP ALG function when processing VoIP signaling, are used to guarantee QoS with respect to the VoIP service, in order to overcome a limitation of the VoIP service occurring when a private network operating a private IP is coupled to a public network using a public IP via a NAT/PT.

According to one aspect of the present invention, a Voice over Internet Protocol (VoIP) call processing system is provided, the system comprising: a first unit adapted to setup address information, for a terminal requesting a call connection during VoIP call signaling, as Quality of Service (QoS) guarantee information for a VoIP service, and to delete the QoS guarantee information upon releasing the VoIP call; and a second unit adapted to guarantee a QoS for the VoIP service according to the QoS guarantee information during the VoIP call.

The address information for the terminal requesting the call connection is preferably one of a public media gateway address corresponding to a private media gateway address assigned from a network to which the terminal belongs to the terminal for providing the VoIP service, and a public network address of the terminal.

The QoS guarantee information preferably comprises address information for the terminal, enables a packet including the address information for the terminal, among packets to be communicated, to be communicated prior to other packets, and excludes the packet including the address information for the terminal from being prioritized for deletion upon an occurrence of packet congestion.

The second unit preferably comprises: a congestion processing module adapted to check whether the QoS guarantee information is included in packets to be communicated with the VoIP call processing system, and to exclude packets including the QoS guarantee information from being prioritized for deletion, upon an occurrence of packet congestion; and a packet processing module adapted to process the communication of packets that are not deleted in the congestion processing module according to priority processing information included in the packets.

The congestion processing module is preferably adapted to perform packet congestion processing using one of a Random Early Detection (RED) method and a Weighted Random Early Detection (WRED) method.

According to another aspect of the present invention, a Voice over Internet Protocol (VoIP) call processing system is provided, the system comprising: a first unit adapted to capture a private network address included in VoIP signaling by performing a VoIP Access Level Gateway (ALG) function, to convert the private network address into a corresponding public network address, and to set up the public network address as Quality of Service (QoS) guarantee information for a VoIP service; and a second unit adapted to guarantee a QoS for the VoIP service according to the QoS guarantee information during the VoIP call.

The first unit is adapted to preferably delete the QoS guarantee information upon releasing the VoIP call.

The first unit is adapted to preferably refer to a Network Address Translation/Port Translation (NAT/PT) table to perform the VoIP ALG function.

The first unit is adapted to preferably refer to the NAT/PT table to convert the private network address into the public network address.

The private network address preferably comprises a private media gateway address assigned to the VoIP call request terminal and the private media gateway address comprises at least one of a media gateway IP address and a media gateway port number.

The QoS guarantee information preferably comprises the public network address, and enables packets including the public network address to be communicated prior to other packets and to be excluded from being prioritized for deletion upon an occurrence of packet congestion.

The second unit preferably comprises a congestion processing module adapted to check whether the QoS guarantee information is included in packets to be communicated with the VoIP call processing system, and to exclude packets including the QoS guarantee information from being prioritized for deletion upon an occurrence of packet congestion; and a packet processing module adapted to process the communication of packets that are not deleted in the congestion processing module according to priority processing information included in the packets.

The congestion processing module is preferably adapted to performs packet congestion processing using one of an random early detection (RED) method and a weighted random early detection (WRED) method.

According to still another aspect of the present invention, a Voice over Internet Protocol (VoIP) call processing method is provided comprising: setting up address information for a terminal requesting a call connection as Quality of Service (QoS) guarantee information for a VoIP service during VoIP call signaling; guaranteeing a QoS for the VoIP service according to the QoS guarantee information during the VoIP call; and deleting the QoS guarantee information upon releasing the VoIP call.

The address information for the terminal requesting the call connection preferably comprises one of a public media gateway address corresponding to a private media gateway address assigned from the network to which the terminal belongs to the terminal for providing the VoIP service, and a public network address of the terminal.

The QoS guarantee information preferably comprises address information for the terminal, and enables packets including the address information for the terminal to be communicated prior to other packets and to be excluded from being prioritized for deletion upon an occurrence of packet congestion.

Guaranteeing the QoS preferably comprises: excluding packets including the QoS guarantee information from being prioritized for deletion upon an occurrence of packet congestion; and processing the communication of packets that are not deleted according to priority processing information included in the packets.

The packet congestion processing is preferably performed by one of a Random Early Detection (RED) method and a Weighted Random Early Detection (WRED) method.

According to yet another aspect of the present invention, a Voice over Internet Protocol (VoIP) call processing method is provided comprising: capturing a private network address included in VoIP signaling by performing a VoIP Access Level Gateway (ALG) function; converting the private network address into a corresponding public network address and setting up the public network address as Quality of Service (QoS) guarantee information for a VoIP service; and guaranteeing a QoS for the VoIP service according to the QoS guarantee information during the VoIP call.

The method preferably further comprises deleting the QoS guarantee information upon releasing the VoIP call.

The VoIP ALG function is preferably performed with reference to a Network Address Translation/Port Translation (NAT/PT) table.

The conversion of the private network address into the public network address is preferably performed using the NAT/PT table.

The private network address preferably comprises a private media gateway address assigned to a VoIP call request terminal and the private media gateway address preferably comprises at least one of a media gateway IP address and a media gateway port number.

The QoS guarantee information preferably comprises the public network address, and enables packets including the public network address to be communicated prior to other packets and to be excluded from being prioritized for deletion upon an occurrence of packet congestion.

Guaranteeing the QoS preferably comprises: excluding packets including the QoS guarantee information from being prioritized for deletion upon an occurrence of packet congestion; and processing the communication of packets that are not deleted according to priority processing information included in the packets.

The packet congestion processing is preferably performed by one of a Random Early Detection (RED) method and a Weighted Random Early Detection (WRED) method.

### BRIEF DESCRIPTION OF THE DRAWINGS

A more complete appreciation of the present invention, and many of the attendant advantages thereof, will be readily apparent as the present invention becomes better understood by reference to the following detailed description when considered in conjunction with the accompanying drawings, in which like reference symbols indicate the same or similar components, wherein:

FIG. 1 is a block diagram of a VoIP call processing system in accordance with an embodiment of the present invention;

FIG. 2 is a NAT/PT table for performing NAT/PT in a VoIP call processing system in accordance with an embodiment of the present invention; and

FIG. 3 is a flowchart of a VoIP call processing method in accordance with an embodiment of the present invention.

### DETAILED DESCRIPTION OF THE INVENTION

The present invention will now be described more fully with reference to the accompanying drawings, in which exemplary embodiments of the present invention are shown. The present invention can, however, be embodied in different forms and should not be construed as being limited to the embodiments set forth herein. Rather, these embodiments are provided so that this disclosure will be thorough and complete, and will fully convey the scope of the present invention to those skilled in the art. In the drawings, whenever the same element reappears in a subsequent drawing, it is denoted by the same reference numeral.

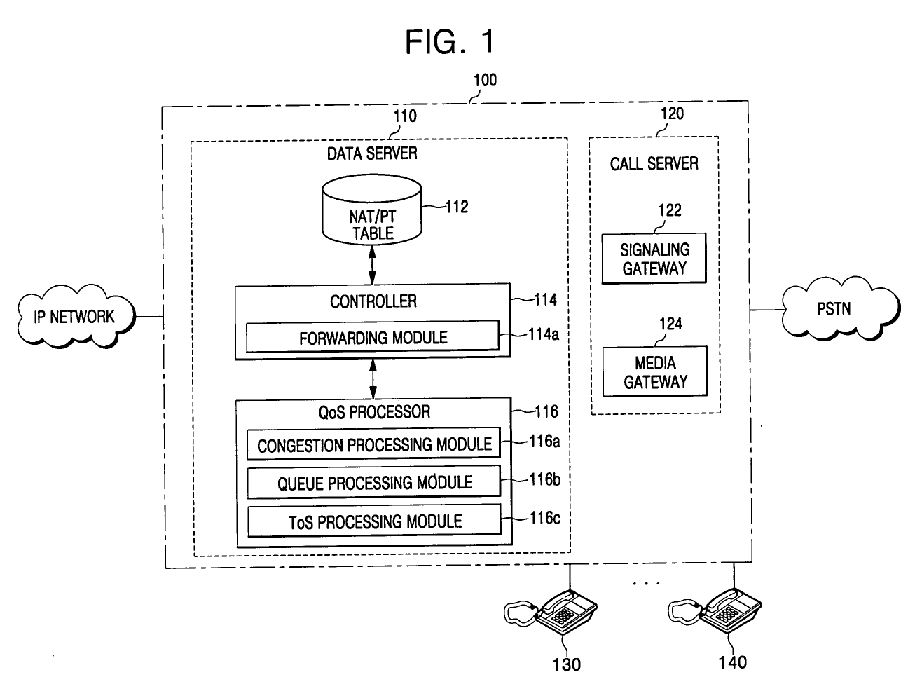

FIG. 1 is a block diagram of a VoIP call processing system in accordance with an embodiment of the present invention.

Referring to FIG. 1, a VoIP call processing system 100 in accordance with the present invention operates using a private IP address and a public IP address. The VoIP call processing system 100 includes a call server 120 that is assigned a signaling IP (private IP) in the VoIP call processing system 100 and performs legacy call signaling and a voice circuit switching function for subscribers of the VoIP call processing system 100, and a data server 110 for performing switching and routing to connect the call server 120 to an IP network so that it provides its subscribers with VoIP services. Communication between the data server 110 and the call server 120 can be performed Through Inter Process Communication (IPC) or an IP network. The present invention applies both in the case of the VoIP call processing system 100 being embodied as an integrated system where the data server 110 and the call server 120 communicate through the IPC, and in the case of the data server 110 and the call server 120 being separate and communicating through an IP network.

The data server 110 has one public IP address assigned in the IP network, and the call server 120 has one signaling IP address (private IP address) that is assigned in the VoIP call processing system 100. At the same time, the data server 110 and call server 120 have ports that are assigned to process media data in the IP assigned to the data server 110 and call server 120.

The data server 110 includes an NAT/PT table storage 112, a controller 114 including a forwarding module 114a, and a QoS processor 116 including a congestion processing module 116a, a queue processing module 116b, and a ToS processing module 116c.

The call server 120 includes a signaling gateway 122 for implementing VoIP signaling and a media gateway 124 for implementing compression conversion processing of VoIP voice data.

The media gateway 124 assigns a channel to each subscriber and performs the compression conversion processing on voice data of each subscriber. The media gateway 124 can assign a Media Gateway Interface (MGI) IP (private IP; for example, 10.10.10.101) and a private port (30000˜30015) with respect to each channel.

If the subscriber wishes to use the VoIP service through the private IP terminal 140 in such an IP network, the call server 120 generates a call connection request message according to telephone number information input by the subscriber and provides it to the data server 110. When the data server 110 receives the call connection request message from the call server 120 and converts a private source IP address into a corresponding public IP address so that an IP terminal of the other party can respond to the call connection request message through the IP network, a call is connected between the private IP terminal 140 in the VoIP call processing system 100 and the IP terminal of the other party, and voice communication is performed according to VoIP. The IP terminal of the other party can have a public IP or a private IP terminal included in an internal network of the other party. The terminal having the public IP of the other party can also be located in the private network of the other party.

As such, in order for the call server 120 having the private IP to form a session and communicate with a call server having a private IP, in the VoIP call processing system 100 that operates using the private IP address and public IP address, an NAT/PT table is needed.

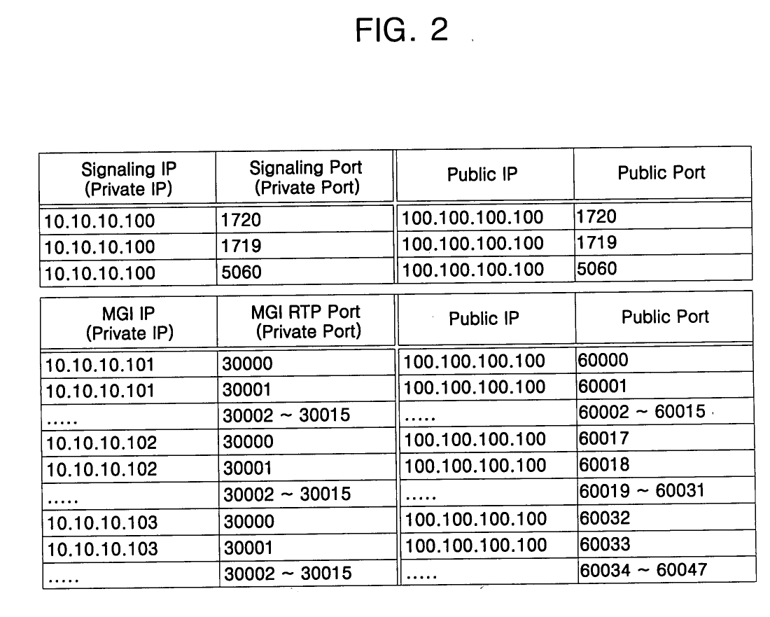

Such an NAT/PT table can be stored in the NAT/PT table storage 112 of the data server 110, an example of which is shown in FIG. 2 and is described below.

When the call server 120 generates the VoIP packet through the signaling gateway 122 and media gateway 124, it loads its signaling IP address and signaling port address on the IP header as a source address, and its MGI IP address and MGI Real Time Protocol (RTP) port address on a Protocol Data Unit (PDU) as a source address.

If a packet is transmitted from the call server 120 to a destination address through the data server 110 by way of the IP network, the controller 114 in the data server 110 converts the signaling IP address and signaling port number loaded on the IP header of the corresponding packet by the call server 120 into a public IP address and public port number with reference to the NAT/PT table stored in the NAT/PT table storage 112.

The controller 114 of the data server 110 converts the MGI IP address and MGI RTP port number loaded on the PDU by the call server 120 into the public IP address and public port number with reference to the NAT/PT table stored in the NAT/PT table storage 112 by performing the VoIP ALG function, and provides the QoS processor 116 with the converted address and number.

Then, the controller 114 of the data server 110 transmits packets including information converted from the signaling IP address and signaling port number into the public IP address and public port number, and information converted from the MGI IP address and MGI RTP port number into the public IP address and public port number, to the IP network through the forwarding module 114a.

The QoS processor 116 provides the congestion processing module 116a, the queue processing module 116b, and the ToS processing module 116c with the public IP address and public port number corresponding to the MGI IP address and MGI RTP port number provided by the controller 114.

The congestion processing module 116a, queue processing module 116b, and ToS processing module 116c enable packets having the public IP address and public port number corresponding to the MGI IP address and MGI RTP port number provided by the controller 114, among transmitted packets, to be subject to a priority policy having a QoS guarantee of the VoIP service.

This can occur when a terminal having a private IP located in an external network makes a call connection request to the terminal 140 having a private IP located in the internal network, as well as when the terminal 140 having a private IP in the internal network makes a call connection request to a terminal having a private IP located in the external network or to a terminal having a public IP.

On the other hand, the terminal 130 having the public IP in the internal network can also be applied in the case of there being a call connection request in a terminal having the public IP located in the external network, or a call connection request in the terminal 130 having the public IP located in the internal network from one of the terminal having the public IP and the terminal having the private IP located in the external network.

Information provided from the controller 114 to the QoS processor 116 to guarantee the QoS for the VoIP service can be one of the public IP address and public port number of the terminal 130 having the public IP located in the internal network, and the public IP address and public port number of the public IP terminal located in the external network.

The congestion processing module 116a can use a Random Early Detection (RED) method and a Weighted Random Early Detection (WRED) method to prevent global synchronization—a packet loss phenomenon occurring when a congestion phenomenon is generated by packets communicated on the network—the WRED method being preferred.

In the RED method, if the measured length of the queue approaches a limit set by a network manager, an arbitrarily specified flow is selected and packets are dropped so that the transmission speed of the transmitter slows down. The RED method is utilized most often in a network needing high transmission speed.

In the WRED method, if congestion occurs, the flow to be dropped is selected according to a specific reference priority (policy). Accordingly, since lower priority packets are selectively dropped, differential performance can be provided depending on the kind of service.

That is, the congestion processing module 116a, while performing congestion processing of packets by the WRED method, can refrain from dropping packets including the public IP address and public port number corresponding to the MGI IP address and MGI RTP port number provided in the controller 114, and the public IP address and public port number with respect to the public IP terminal located in the internal and external networks, among packets causing the congestion phenomenon. By doing so, packets for the VoIP service can be transmitted to guarantee the QoS of the VoIP service.

The queue processing module 116b can process the queue in a round robin fashion and enable packets including the public IP address and public port number corresponding to the MGI IP address and MGI RTP port number provided in the controller 114, and the public IP address and public port number with respect to the public IP terminal located in the internal and external networks, to be put in the higher priority queue among the queues awaiting transmission.

If packets to be communicated include the public IP address and public port number corresponding to the MGI IP address and MGI RTP port number provided in the controller 114, and the public IP address and public port number with respect to the public IP terminal located in the internal and external networks, the ToS processing module 116c sets the ToS field included in the packets to high priority so as to preferentially process the packets.

The controller 114 provides the QoS processor 116 with the packets to be communicated starting from when a priority (policy) setup for the QoS guarantee with respect to the VoIP service is performed in the QoS processor 116, until the end of a VoIP call between one of the private IP terminal in the internal network and the public IP terminal and one of the private IP terminal located in the external network and the public IP terminal, and processes the corresponding packets according to the priority (policy) set up to guarantee the QoS for the VoIP service.

The QoS processor 116 performs operations to guarantee the QoS for the VoIP service with respect to the communicated packets provided in the controller 114.

The above operations are described below in detail.

When address information of the terminal included in the transmission/reception packet is compared with address information set up in order of priority to guarantee the QoS for the VoIP service in the congestion processing module 116a, and both bits of information are identical, the packet is not prioritized for dropping during congestion processing. The address information of each terminal included in the packet to be communicated can be the public IP address and public port number corresponding to the MGI IP address and MGI RTP port number when a private IP terminal is located in the internal and external networks, and the public IP address and public port number when the public IP terminal is located in the internal and external networks.

When the ToS processing module 116c checks the ToS field included in the transmission/reception packet provided from the controller 114, and the ToS field includes the priority information, the packet is assigned to a queue of the queue processing module 116c according to the priority information of the ToS field and is transmitted. In contrast, when the ToS field included in the transmission/reception packet provided from the controller 114 does not include the priority information, the packet is assigned to a queue of the queue processing module 116c according to a processing request order of the corresponding packet. In this case, the queue processing module 116c processes and transmits the packet according to the order assigned to the queue.

As described above, it is desirable that the operations to guarantee the QoS for the VoIP with respect to the transmission/reception packet in the QoS processor 116 are performed in the order of the congestion processing module 116a first, the ToS processing module 116c second, and the queue processing module 116b last.

Subsequently, at the end of a call between terminals located in the internal and external networks, the controller 114 deletes and processes the priority information set up in the QoS processor 116 to guarantee the QoS of the VoIP service. In other words, at the end of a call between the terminals located in the internal and external networks, the congestion processing module 116a deletes and processes the address information of each terminal included in transmission/reception packets set up not to be prioritized for dropping when congestion occurs.

FIG. 2 is a NAT/PT table used to perform NAT/PT in a VoIP call processing system in accordance with an embodiment of the present invention.

The NAT/PT table of FIG. 2 can be stored in the NAT/PT table storage 112 of FIG. 1, which is described briefly below.

Referring to FIG. 2, the NAT/PT table is generally divided into a data region loaded in the IP header and a data region loaded in PDU.

Reviewing the data region loaded in the IP header, there is a signaling IP (private IP; 10.10.10.100) assigned to the call server 120, a signaling port (private port; 1720,1719,5060), a public IP (100.100.100.100) for each private IP, and a public port (1720,1719,5060) for each private port.

Reviewing the data region loaded in the PDU, there is an MGI IP (private IP; 10.10.10.101, 10.10.10.102, 10.10.10.103) assigned to the media gateway, and an MGI RTP port (private port; 30000˜30015) for each MGI IP. 16 ports are assigned to one IP. Furthermore, there is a public IP (100.100.100.100) for each private IP, and a public port (60000˜60047) for each private port.

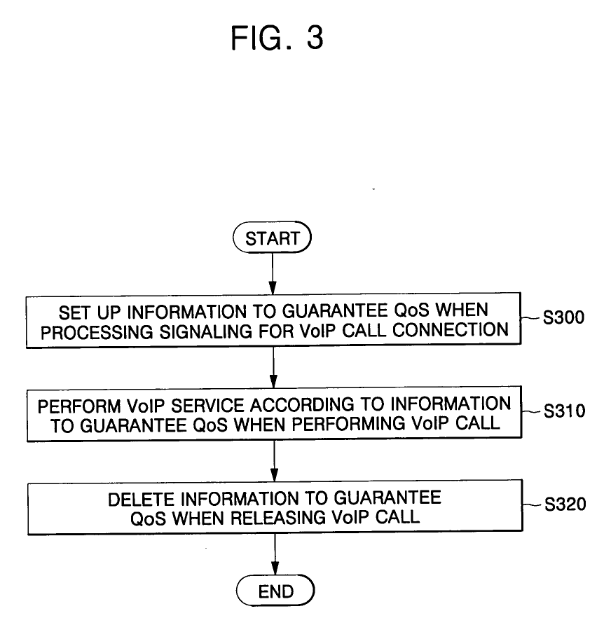

FIG. 3 is a flowchart of a VoIP call processing method in accordance with an embodiment of the present invention.

Referring to FIG. 3, if signaling of a VoIP call connection is processed according to a VoIP call connection request from a first terminal to a second terminal via an IP network, address information of the first terminal is set up as information to guarantee the QoS for the VoIP service. Conversely, if signaling of a VoIP call connection is processed according to a VoIP call connection request from the second terminal to the first terminal via the IP network, address information of the second terminal can be set up as information to guarantee the QoS for the VoIP service (S300).

It is desirable that the first and second terminals are located on different networks and can have a private IP or a public IP on their respective networks.

The first terminal address information and second terminal address information can be the public IP address and public port in the case of each terminal having a public IP in its corresponding network. If the first and second terminals are connected to the call server 120 having the private IP of FIG. 1 in their corresponding networks, and perform the VoIP service, a Media Gateway Interface (MGI) IP (private IP) and MGI RTP port (private port) are assigned by the media gateway 124 in the call server 120 in order to provide the VoIP service.

In order for the first and second terminals to perform the VoIP service with a terminal included in any network except the network to which the terminals belong, the MGI IP and MGI RTP port must be converted into the public IP and public port using a NAT/PT table such as that of FIG. 2. The address information of the first and second terminals can correspond to the public IP and public port converted in the MGI IP and MGI RTP port for the terminals, respectively.

Then, if the packet including address information to guarantee the QoS is communicated during the VoIP service between terminals connected to the VoIP, the QoS is guaranteed for the VoIP by setting up the corresponding packet to be communicated preferentially (S310).

Reviewing the above in more detail, in order to guarantee the QoS for the VoIP service, address information of the terminal included in the transmission/reception packet and information to guarantee the QoS for the VoIP service are compared, and if the information is identical, the packet is set up not to be dropped during congestion processing. The address information of each terminal included in the packet to be communicated can be the public IP address and public port number corresponding to the MGI IP address and MGI RTP port number in the case of the private IP terminal in the network where each terminal is located, and the public IP address and public port number in the case of the public IP terminal in the internal and external networks.

The ToS field included in the transmission/reception packet that is not dropped during congestion processing is checked, and if the packet's priority is indicated in the corresponding ToS field, the packet is assigned to the queue according to the priority indicated in the ToS field, and is thereafter communicated.

On the other hand, if the ToS field included in the transmission/reception packet that was not dropped during congestion processing does not include priority information, the packet is assigned to a queue according to a processing request order of the corresponding packet. In this case, processing and communication of the packet is performed according to the order assigned to the queue.

Thus, according to the present invention, the QoS for the VoIP service can be guaranteed by performing congestion processing and then processing packets that are not dropped according to priority information in the ToS field.

At the end of a VoIP call between terminals, information to guarantee the QoS of the VoIP service is deleted (S320). For example, address information of terminals set up to prevent dropping of certain packets in the event of congestion is deleted when the VoIP call ends.

As described above, according to the VoIP call processing system and method of the present invention, it is possible to guarantee the QoS for the VoIP service by using the VoIP IP address and port number for the VoIP service, obtained by performing the VoIP ALG function when processing the VoIP signaling, as information to guarantee the QoS for the VoIP service. The present invention thereby overcomes a limitation of the VoIP service occurring in the case of a private network operating using a private IP coupling with a public network using a public IP via NAT/PT.

Furthermore, the present invention alleviates the need to previously set up the IP address and port used to guarantee the QoS for the VoIP service. This is accomplished by setting up the address information of the terminal that requested the call connection as information to guarantee the QoS when processing signaling for the VoIP call connection, performing the VoIP service according to the information to guarantee the QoS, and deleting the information used to guarantee the QoS when the VoIP call ends. In the event of congestion, the present invention can guarantee the QoS for the VoIP service by preferentially processing packets including the information to guarantee the QoS.

While the present invention has been described with reference to exemplary embodiments thereof, it will be understood by those skilled in the art that various modifications in form and detail can be made therein without departing from the spirit and scope of the present invention as defined by the following claims.

What is claimed is

1. A Voice over Internet Protocol (VoIP) call processing system, comprising:
a first unit adapted to setup address information, for a terminal requesting a call connection during VoIP call signaling, as Quality of Service (QoS) guarantee information for a VoIP service, and to delete the QoS guarantee information upon releasing the VoIP call; and
a second unit adapted to guarantee a QoS for the VoIP service according to the QoS guarantee information during the VoIP call.

2. The system according to claim 1, wherein the address information for the terminal requesting the call connection comprises one of a public media gateway address corresponding to a private media gateway address assigned from a network to which the terminal belongs to the terminal for providing the VoIP service, and a public network address of the terminal.

3. The system according to claim 1, wherein the QoS guarantee information comprises address information for the terminal, enables a packet including the address information for the terminal, among packets to be communicated, to be communicated prior to other packets, and excludes the packet including the address information for the terminal from being prioritized for deletion upon an occurrence of packet congestion.

4. The system according to claim 1, wherein the second unit comprises:
a congestion processing module adapted to check whether the QoS guarantee information is included in packets to be communicated with the VoIP call processing system, and to exclude packets including the QoS guarantee information from being prioritized for deletion, upon an occurrence of packet congestion; and
a packet processing module adapted to process the communication of packets that are not deleted in the congestion processing module according to priority processing information included in the packets.

5. The system according to claim 4, wherein the congestion processing module is adapted to perform packet congestion processing using one of a Random Early Detection (RED) method and a Weighted Random Early Detection (WRED) method.

6. A Voice over Internet Protocol (VoIP) call processing system, comprising:
a first unit adapted to capture a private network address included in VoIP signaling by performing a VoIP Access Level Gateway (ALG) function, to convert the private network address into a corresponding public network address, and to set up the public network address as Quality of Service (QoS) guarantee information for a VoIP service; and
a second unit adapted to guarantee a QoS for the VoIP service according to the QoS guarantee information during the VoIP call.

7. The system according to claim 6, wherein the first unit is adapted to delete the QoS guarantee information upon releasing the VoIP call.

8. The system according to claim 6, wherein the first unit is adapted to refer to a Network Address Translation/Port Translation (NAT/PT) table to perform the VoIP ALG function.

9. The system according to claim 8, wherein the first unit is adapted to refer to the NAT/PT table to convert the private network address into the public network address.

10. The system according to claim 6, wherein the private network address comprises a private media gateway address assigned to the VoIP call request terminal and the private media gateway address comprises at least one of a media gateway IP address and a media gateway port number.

11. The system according to claim 6, wherein the QoS guarantee information comprises the public network address, and enables packets including the public network address to be communicated prior to other packets and to be excluded from being prioritized for deletion upon an occurrence of packet congestion.

12. The system according to claim 6, wherein the second unit comprises a congestion processing module adapted to check whether the QoS guarantee information is included in packets to be communicated with the VoIP call processing system, and to exclude packets including the QoS guarantee information from being prioritized for deletion upon an occurrence of packet congestion; and
a packet processing module adapted to process the communication of packets that are not deleted in the congestion processing module according to priority processing information included in the packets.

13. The system according to claim 12, wherein the congestion processing module is adapted to performs packet congestion processing using one of an random early detection (RED) method and a weighted random early detection (WRED) method.

14. A Voice over Internet Protocol (VoIP) call processing method comprising:
setting up address information for a terminal requesting a call connection as Quality of Service (QoS) guarantee information for a VoIP service during VoIP call signaling;
guaranteeing a QoS for the VoIP service according to the QoS guarantee information during the VoIP call; and
deleting the QoS guarantee information upon releasing the VoIP call.

15. The method according to claim 14, wherein the address information for the terminal requesting the call connection comprises one of a public media gateway address corresponding to a private media gateway address assigned from the network to which the terminal belongs to the terminal for providing the VoIP service, and a public network address of the terminal.

16. The method according to claim 14, wherein the QoS guarantee information comprises address information for the terminal, and enables packets including the address information for the terminal to be communicated prior to other packets and to be excluded from being prioritized for deletion upon an occurrence of packet congestion.

17. The method according to claim 14, wherein guaranteeing the QoS comprises:
excluding packets including the QoS guarantee information from being prioritized for deletion upon an occurrence of packet congestion; and
processing the communication of packets that are not deleted according to priority processing information included in the packets.

18. The method according to claim 17, wherein the packet congestion processing is performed by one of a Random Early Detection (RED) method and a Weighted Random Early Detection (WRED) method.

19. A Voice over Internet Protocol (VoIP) call processing method comprising:
capturing a private network address included in VoIP signaling by performing a VoIP Access Level Gateway (ALG) function;
converting the private network address into a corresponding public network address and setting up the public network address as Quality of Service (QoS) guarantee information for a VoIP service; and
guaranteeing a QoS for the VoIP service according to the QoS guarantee information during the VoIP call.

20. The method according to claim 19, further comprising deleting the QoS guarantee information upon releasing the VoIP call.

21. The method according to claim 19, wherein the VoIP ALG function is performed with reference to a Network Address Translation/Port Translation (NAT/PT) table.

22. The method according to claim 21, wherein the conversion of the private network address into the public network address is performed using the NAT/PT table.

23. The method according to claim 19, wherein the private network address comprises a private media gateway address assigned to a VoIP call request terminal and the private media gateway address comprises at least one of a media gateway IP address and a media gateway port number.

24. The method according to claim 19, wherein the QoS guarantee information comprises the public network address, and enables packets including the public network address to be communicated prior to other packets and to be excluded from being prioritized for deletion upon an occurrence of packet congestion.

25. The method according to claim 19, wherein guaranteeing the QoS comprises:
excluding packets including the QoS guarantee information from being prioritized for deletion upon an occurrence of packet congestion; and
processing the communication of packets that are not deleted according to priority processing information included in the packets.

26. The method according to claim 25, wherein the packet congestion processing is performed by one of a Random Early Detection (RED) method and a Weighted Random Early Detection (WRED) method.
